(19) United States
(12) Patent Application Publication
(10) Pub. No.: US 2012/0025258 A1
(43) Pub. Date: Feb. 2, 2012

(54) LIGHT EMITTING DIODE PACKAGE AND LIGHT EMITTING DIODE MODULE

(75) Inventors: SHIUN-WEI CHAN, Hsinchu (TW); CHIH-HSUN KE, Hsinchu (TW); HSING-FEN LO, Hsinchu (TW)

(73) Assignee: ADVANCED OPTOELECTRONIC TECHNOLOGY, INC., Hsinchu Hsien (TW)

(21) Appl. No.: 13/029,126

(22) Filed: Feb. 17, 2011

(30) Foreign Application Priority Data
Jul. 28, 2010 (CN) 201010239123.2

(51) Int. Cl. H01L 33/48

(52) U.S. Cl. 257/99; 257/E33.058

(57) ABSTRACT

An exemplary LED module includes a board and an LED package mounted on the plate. The LED package includes a base, an LED chip mounted on a top surface of the base, two electrodes formed on the base and electrically connected to the LED chip and the board, and an encapsulant encapsulating the LED chip. A plurality of grooves are defined in the bottom surface of the base. When the LED package is secured on the plate via solder paste, the grooves function as a container for receiving excessive solder paste, thereby preventing the solder paste from spilling and floating or inclination of the LED package.

### BACKGROUND

1. Technical Field

The present disclosure relates generally to light emitting devices, and more particularly to a light emitting diode (LED) package and an LED module having the LED package.

2. Description of Related Art

LEDs are solid state light emitting devices formed of semiconductors, which are more stable and reliable than other conventional light sources such as incandescent bulbs. Thus, LEDs are being widely used in various fields such as numeral/character displaying elements, signal lights, light sources for lighting and display devices. When in use, providing LEDs in packages can provide protection, color selection, focusing and the like for light emitted by the LEDs.

A typical LED package includes a base with an LED chip encapsulated thereon. The LED package is generally formed as a surface mounting type device for facilitating application, whereby the base is mounted on a printed circuit board or other similar elements. Solder paste such as tin is used between the base and the printed circuit board for soldering the LED package on the printed circuit board. However, the existent of solder paste easily results in floating or inclination of the LED package. When heating the solder paste to bond the LED package onto the printed circuit board, the solder paste is prone to spill over the base of the LED package. The above mentioned factors not only interfere the soldering of the LED package, but also destroy aesthetics of the LED package. In addition, the solder paste is also prone to generate voids therein due to heating flux thereof, which increases a heat resistance of the solder paste and negatively affects the heat dissipation of the LED package.

What is needed therefore is an LED package and an LED module having the LED package which can overcome the above mentioned limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is a side view of an LED package in accordance with a first embodiment of the present disclosure.

FIG. 2 is a cross sectional view of an LED package in accordance with a second embodiment of the present disclosure.

FIG. 3 is a cross sectional view of an LED package in accordance with a third embodiment of the present disclosure.

FIG. 4 is a cross sectional view of an LED package in accordance with a forth embodiment of the present disclosure.

FIG. 5 is a top view of an LED package in accordance with a fifth embodiment of the present disclosure.

FIG. 6 is a cross sectional view of the LED package shown in FIG. 5, taken along line VI-VI thereof.

FIG. 7 is a top view of an LED package in accordance with a sixth embodiment of the present disclosure.

FIG. 8 is a cross sectional view of the LED package shown in FIG. 7, taken along line VIII-VIII thereof.

FIG. 9 is a cross sectional view of an LED package in accordance with a seventh embodiment of the present disclosure.

FIGS. 10 and 11 are bottom views of bases of LED packages in different embodiments of the present disclosure.

FIG. 12 is a cross sectional view of an LED module in accordance with an embodiment of the present disclosure.

### DETAILED DESCRIPTION

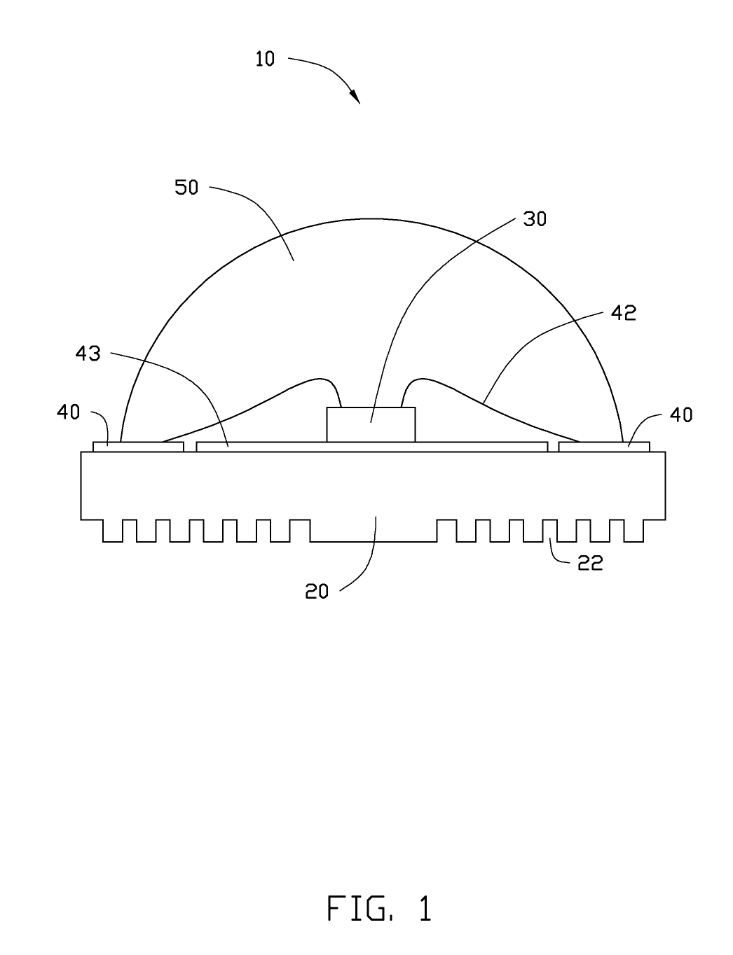

FIG. 1 illustrates an LED package 10 in accordance with an embodiment of the present disclosure. The LED package 10 includes a base 20, an LED chip 30 mounted on a surface of the base 20, two electrodes 40 formed on the base 20 and electrically connected to the LED chip 30, and an encapsulant 50 encapsulating the LED chip 30. At least one groove 22 is defined in a surface of the base 20 opposite the LED chip 30.

The base 20 may be plastic, ceramics, or other insulating materials. The base 20 may be rectangular, round or polygonal in shape. The LED chip 30 is mounted on a first surface such as a top surface of the base 20.

The LED chip 30 is connected to the electrodes 40 with metal wires 42 by wire bonding. It is understood that the LED chip 30 may also be connected to the electrodes 40 by flip chip technique in an alternative embodiment.

In the present embodiment, the at least one groove 22 is configured to be plural. The grooves 22 are straight, parallel to each other and defined in a second surface such as a bottom surface of the base 20. A cross section of each groove 22 can be rectangular, arc, polygonal or other suitable geometric configurations. The grooves 22 defined in the bottom surface of the base 20 increase a surface area of the base 20 and are capable of receiving more solder paste therein, which is benefit for avoiding inclination of the LED package 10 or spill of the solder paste when bonding the LED package 10 to a printed circuit board or other similar elements. Further, the grooves 22 may function as vents for air generated by the solder paste when heated, whereby voids defined by the air in the solder paste can be prevented. Specifically, in this embodiment, the grooves 22 extend to an edge of the base 20 and communicate with an outside of the base 20 for obtaining a better function of air evacuation. A depth of the grooves 22 is generally ⅕-½ of a thickness of the base 20. The base 20 having the grooves 22 with such a depth provides an acceptable strength and meanwhile an acceptable receiving space for the solder paste. Metal may be plated on the bottom surface of the base 20 defining all or a portion of the grooves 22, for easily adhering the solder paste to the base 20.

The encapsulant 50 is transparent or translucent, and may be made of resins, glass or other suitable materials. The encapsulant 50 can be configured as spherical, elliptical, or rectangular.

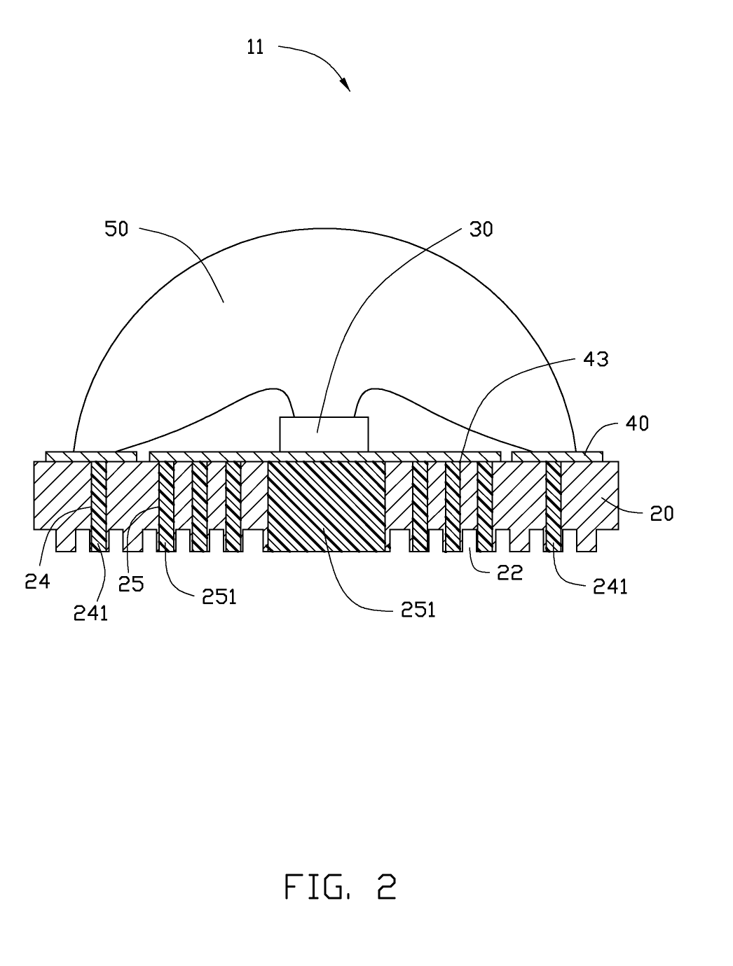

Referring to FIG. 2, an LED package 11 in accordance with an embodiment of the present disclosure further includes a plurality of electrically conductive holes 24 and heat conductive holes 25 defined in the base 20. The electrically conductive holes 24 and heat conductive holes 25 extend from the top surface through the bottom surface of the base 20. Electrically conductive materials 241 and heat conductive materials 251 such as metal are respectively received in the electrically conductive holes 24 and heat conductive holes 25. The electrically conductive materials 241 are connected to the electrodes 40. The heat conductive materials 251 have a higher heat conductivity than the base 20 and connect to a metal layer 43 mounted on the base 20. Heat generated by the LED chip 30 can be transferred by the metal layer 43 and the heat conductive materials 251. Specially, a heat conductive hole 25 corresponding to the position of the LED chip 30 is larger than other heat conductive holes 25, which is an advantage for heat dissipation of the LED chip 30. The electrically conductive holes 24 and heat conductive holes 25 may be round, rectangular, square in a top view. The cross sections of the electrically conductive holes 24 and heat conductive holes 25 may be rectangular, trapeziform or other shapes.

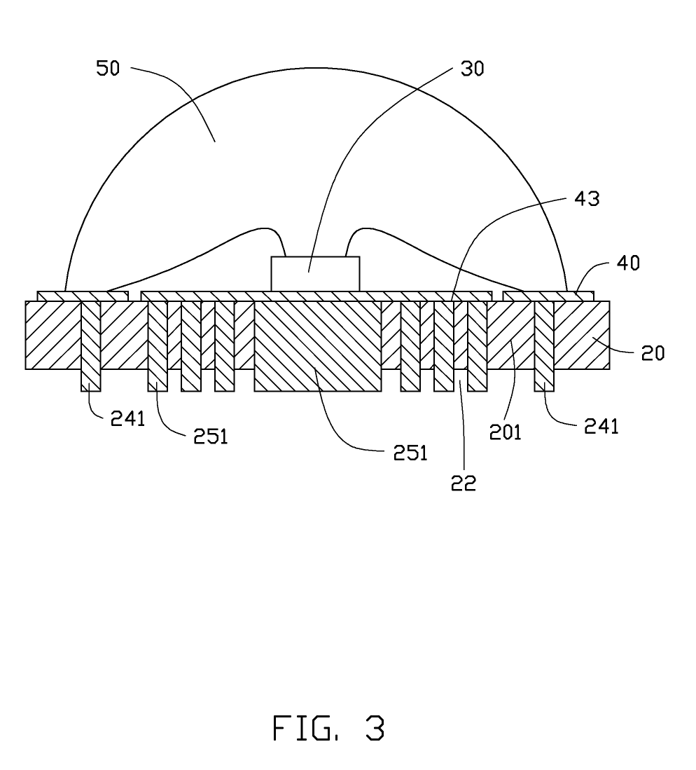

The grooves 22 are defined in the base 20 by machining the base 20 in the previous embodiments. It is understood that the grooves 22 can also be defined by other fashions. Referring to FIG. 3, the base 20 in a third embodiment comprises a plurality of plate-shaped electrically conductive materials 241 and heat conductive materials 251 (such as metal), and a plurality of plate-shaped, electrically isolating materials 201 (such as ceramics, plastic, etc.) presented in an alternating fashion. The electrically conductive materials 241 and heat conductive materials 251, and the isolating materials 201 are vertically placed. The electrically conductive materials 241 and heat conductive materials 251 are higher than the isolating materials 201. Tops of the electrically conductive materials 241, heat conductive materials 251 and insolating materials 201 are flushed with each other, whereby grooves 22 are defined between bottoms of neighboring electrically conductive materials 241, heat conductive materials 251 and isolating materials 201.

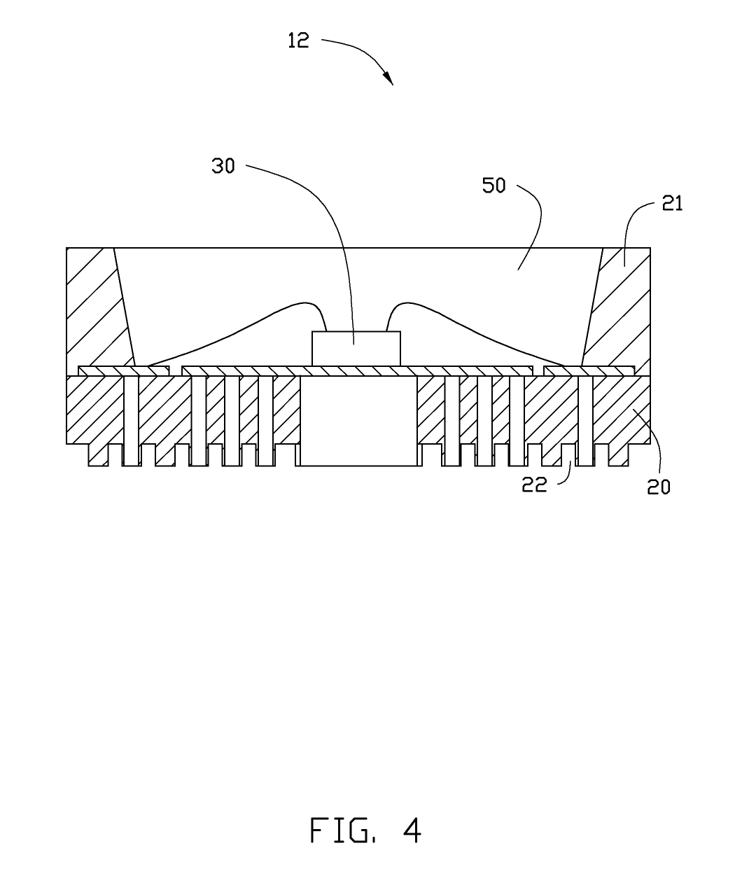

An LED package 12 in accordance with a forth embodiment of the present disclosure is illustrated in FIG. 4. The LED package 12 further comprises a reflection cup 21 formed on the top surface of the base 20. The LED chip 30 is positioned at a bottom of the reflection cup 21. The encapsulant 50 is received in the reflection cup 21. The reflection cup 21 and the base 20 can be formed integrally in an alternative embodiment. An angle defined between the top surface of the base 20 and a reflecting surface (i.e., an inner surface) of the reflection cup 21 can be 90-130 degrees.

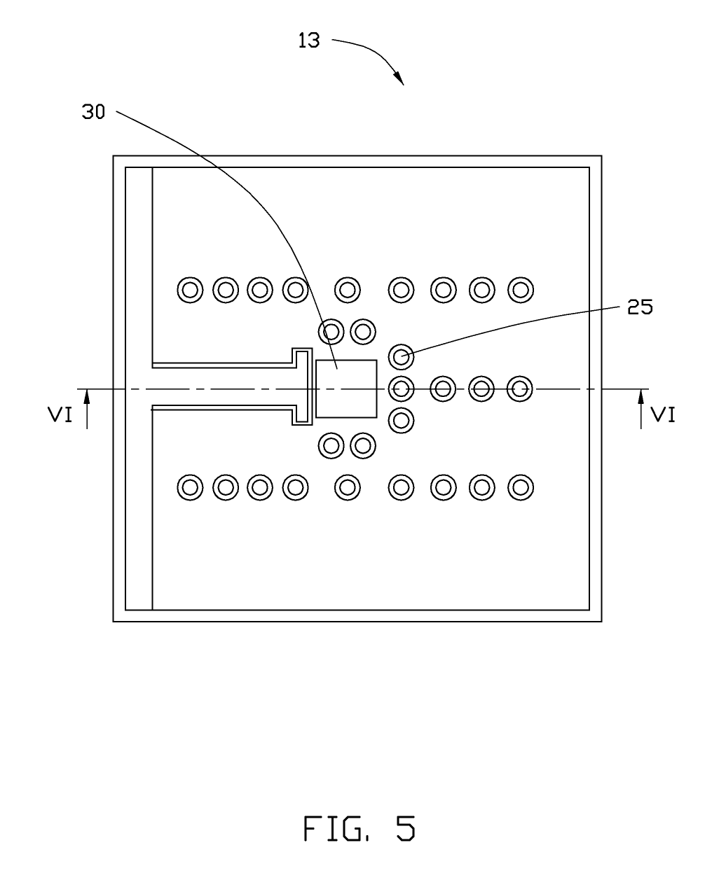

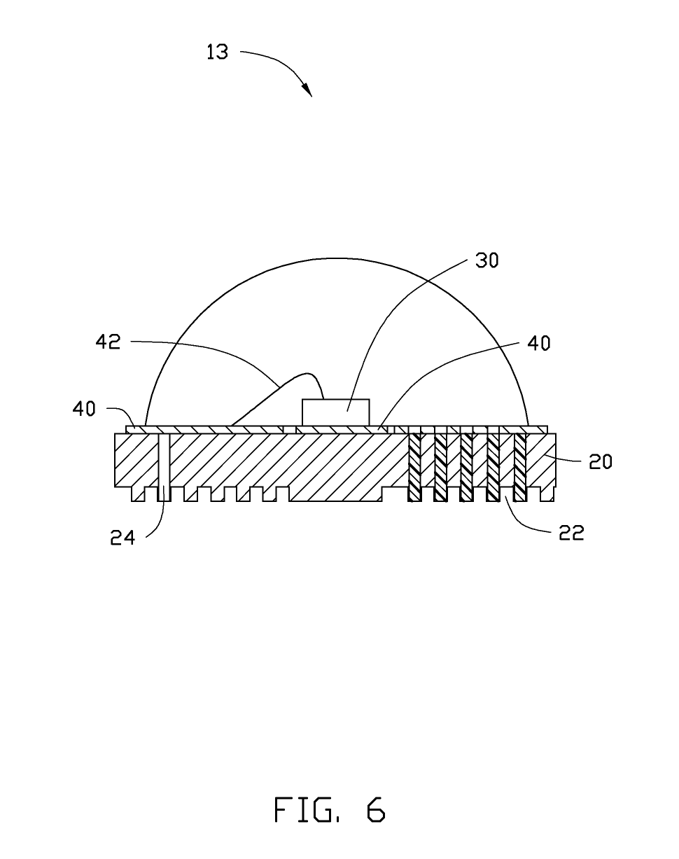

Referring to FIGS. 5 and 6, the LED chip 30 of an LED package 13 in accordance with a fifth embodiment of the present disclosure is a vertical type LED chip. A bottom of the LED chip 30 is directly connected to an electrode 40 to accomplish an electrical connection. A top of the LED chip 30 is electrically connected to another electrode 40 via a metal wire 42. A plurality of electrically conductive holes 24 and heat conductive holes 25 are defined in the base 20, and electrically conductive materials and heat conductive materials are respectively received in the electrically conductive holes 24 and heat conductive holes 25. Specially, a density of the heat conductive holes 25 around the LED chip 30 is higher than that at other positions. Thus, heat generated by the LED chip 30 can be dissipated more efficiently.

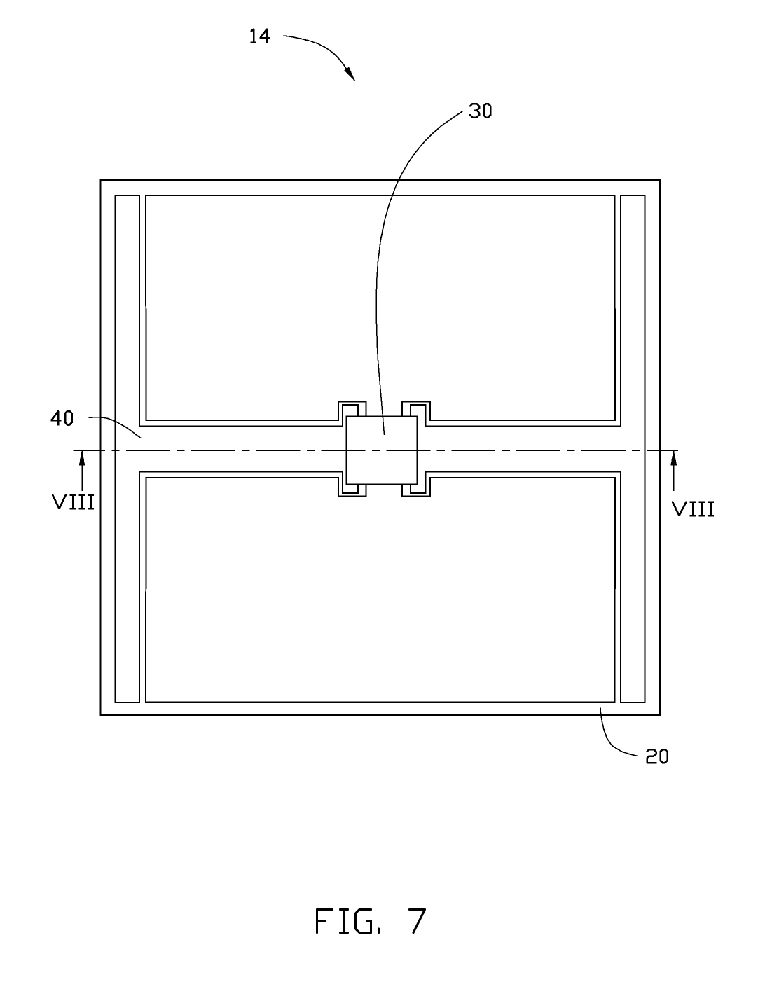

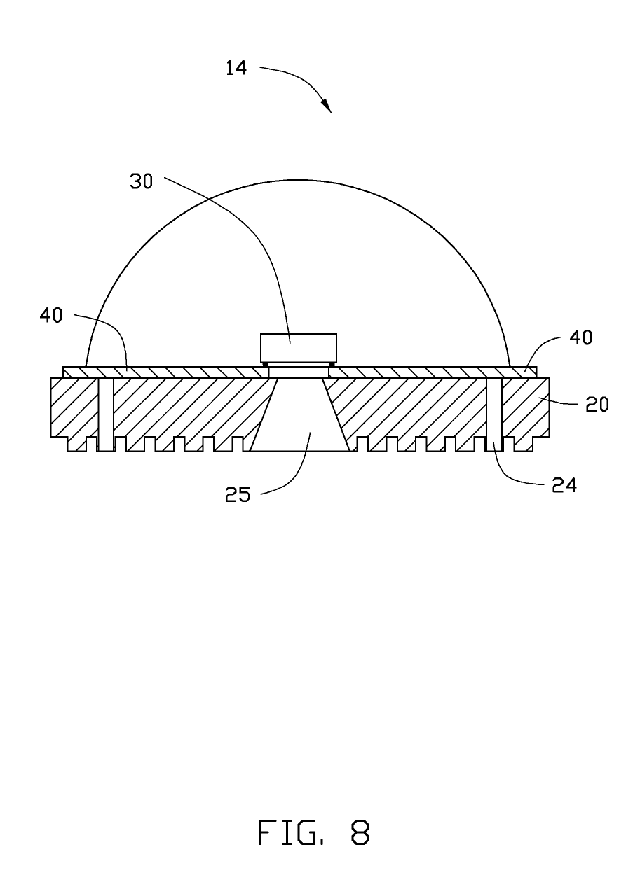

Referring to FIGS. 7 and 8, the LED chip 30 of an LED package 14 in accordance with a sixth embodiment of the present disclosure is mounted on the base 20 by a flip chip technique. The LED chip 30 connects the electrodes 40 for obtaining electrical power. One of the heat conductive holes 25 in the base 20 has a square shape in a top view, and a cross section of the heat conductive hole 25 is trapeziform.

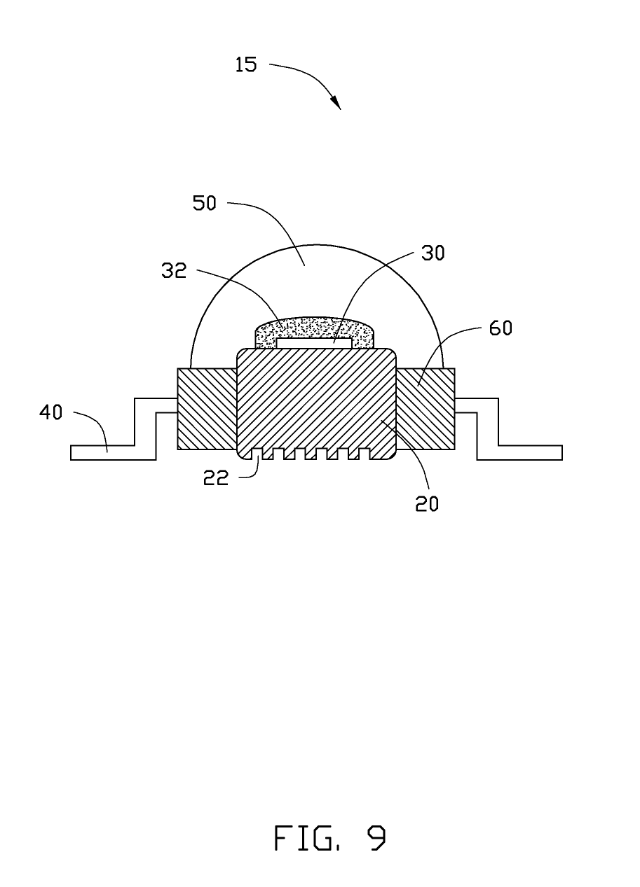

An LED package 15 in accordance with a seventh embodiment of the present disclosure shown in FIG. 9 comprises a substantially columned base 20, an LED chip 30 mounted on a top surface of the base 20, two electrodes 40 formed on the base 20 and electrically connected to the LED chip 30, and an encapsulant 50 encapsulating the LED chip 30. A plurality of grooves 22 are defined in a bottom surface of the base 20. The base 20 is made of a material with high heat conductivity, and heat generated by the LED chip 30 can be dissipated by the base 20. A phosphor layer 32 covers the LED chip 30. The phosphor layer 32 may contain YAG phosphors, silicon oxynitride phosphors, nitride phosphors, etc. The LED package 15 further comprises a substrate 60 surrounding the base 20. The electrodes 40 extend out from the substrate 60 and are flush with the bottom surface of the base 20.

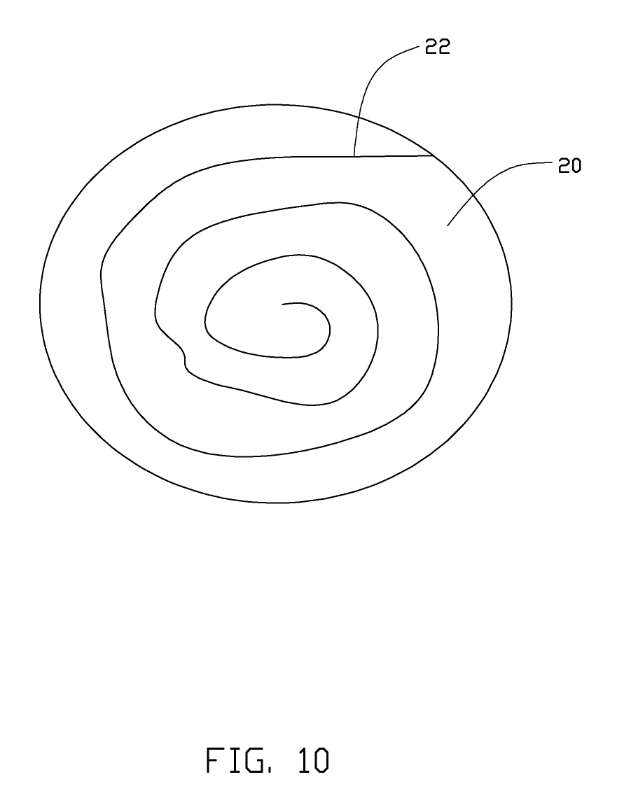

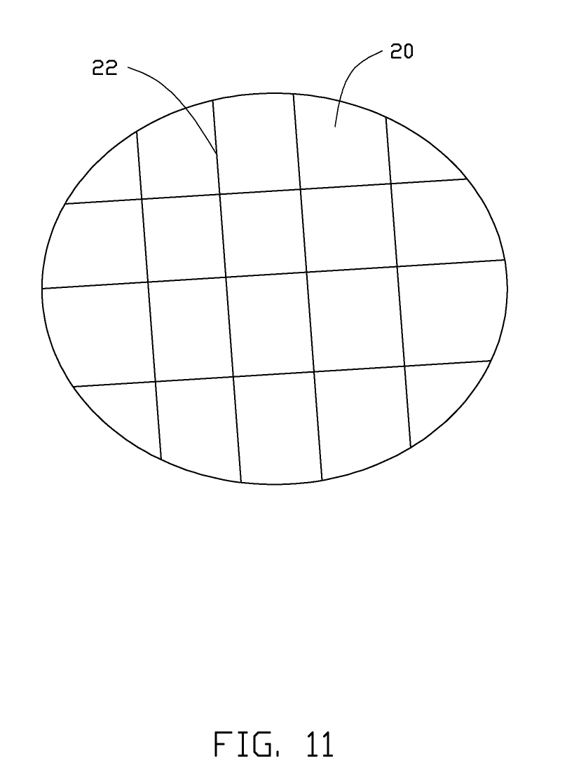

A plurality of grooves 22 with different fashions defined in the base 20 are shown in FIGS. 10 and 11. The grooves 22 may present as curved or net configuration. The grooves 22 extend to an edge of the base 20 and communicate with the outside of the base 20.

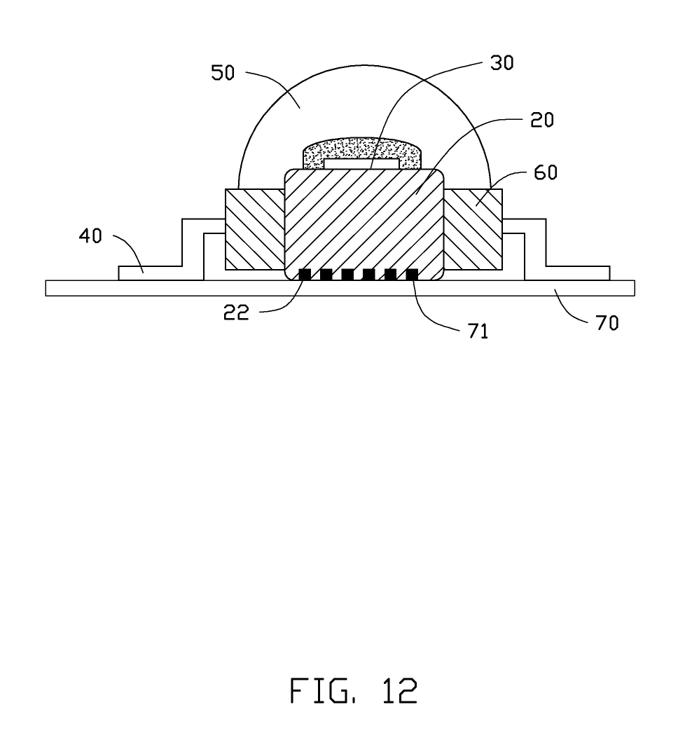

Referring to FIG. 12, an LED module in accordance with an embodiment of the present disclosure includes a board 70 such as a printed circuit board, and an LED package mounted on the board 70. The LED package is identical to the LED package 15 shown in FIG. 9. The bottom surface of the base 20, in which the grooves 22 are defined, is attached to the board 70. It is noted that the LED package can be any LED package shown in the previous embodiments. It is further noted that in one embodiment, the grooves 22 can be formed by different fashions shown in such as the first and third embodiments. The LED package is secured on the board 70 by the solder paste 71. The grooves 22 positioned at the bottom surface of the base 20 can serve as a container for receiving excessive solder paste 71, preventing the excessive solder paste from spilling over the base 20. Floating and inclination of the LED package due to the excessive solder paste can also be avoided. The electrodes 40 are electrically connected to the board 70 by soldering, for example, surface mounting technology (SMT).

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A light emitting diode (LED) package comprising a base, an LED chip mounted on a first surface of the base, electrodes formed on the base and electrically connected to the LED chip, and an encapsulant encapsulating the LED chip, wherein at least one groove is defined in a second surface of the base for receiving solder paste by which the LED package is adhered to a board.

2. The LED package of claim 1, wherein the at least one groove extends to an edge of the base and communicates with an outside of the base.

3. The LED package of claim 1, wherein the at least one groove is configured to be straight, curved or nets.

4. The LED package of claim 1, wherein the second surface of the base defining the at least one groove is at least partially plated with metal.

5. The LED package of claim 1, wherein a plurality of electrically conductive holes and heat conductive holes are defined in the base, the electrically conductive holes and heat conductive holes extending through the first and second surfaces of the base, and electrically conductive materials and heat conductive materials being respectively received in the electrically conductive holes and heat conductive holes.

6. The LED package of claim 5, wherein a density of the heat conductive holes at a position near the LED chip is larger than that far from the LED chip.

7. The LED package of claim 1, wherein a depth of the at least one groove is ⅕-½ of a thickness of the base.

8. The LED package of claim 1 further comprising a substrate surrounding the base, the electrodes extending out of the substrate and being flush with the second surface of the base.

9. The LED package of claim 1, wherein the base comprises a plurality of electrically insulating materials, electrically conductive materials and heat conductive materials having different heights and arranged in an alternating fashion, the at least one groove being defined at neighboring insulating materials, electrically conductive materials and heat conductive materials.

10. An LED module comprising:
a board; and
an LED package secured on the board via solder paste, the LED package comprising a base, an LED chip mounted on a first surface of the base, electrodes connected to the LED chip and the board, and an encapsulant encapsulating the LED chip;
wherein at least one groove is defined in a second surface of the base for receiving the solder paste.

11. The LED module of claim 10, wherein the at least one groove extends to an edge of the base and communicates with an outside of the base.

12. The LED module of claim 10, wherein the at least one groove is configured to be straight, curved or nets.

13. The LED module of claim 10, wherein a depth of the at least one groove is ⅕-½ of a thickness of the base.

14. The LED module of claim 10, wherein the second surface of the base defining the at least one groove is plated with metal.

15. An LED module comprising:
a board; and
an LED package secured on the board via solder paste, the LED package comprising a base, an LED chip mounted on a top surface of the base, electrodes formed on the base and electrically connected to the LED chip and the board, and an encapsulant encapsulating the LED chip;
wherein a plurality of grooves are defined in a bottom surface of the base for receiving the solder paste.

16. The LED module of claim 15, wherein the base comprises a plurality of plated-shaped electrically insulating materials, plated-shape electrically conductive materials and plated-shape heat conductive materials with different heights placed vertically and presented in an alternating fashion, tops of the electrically insulating materials, electrically conductive materials and heat conductive materials being flushed with each other, and the grooves being defined at bottoms of neighboring insulating materials, electrically conductive materials and heat conductive materials.

17. The LED module of claim 15, wherein the grooves extend to an edge of the base and communicate with an outside of the base.

18. The LED module of claim 15, wherein the bottom surface of the base defining the grooves is at least partially plated with metal.
